(19) United States
(12) Patent Application Publication
(10) Pub. No.: US 2025/0206188 A1
(43) Pub. Date: Jun. 26, 2025

(54) BATTERY SYSTEM AND ELECTRIFIED VEHICLE

(71) Applicant: TOYOTA JIDOSHA KABUSHIKI KAISHA, Toyota-shi (JP)

(72) Inventors: Yuki SUGO, Seto-shi (JP); Takashi Ogura, Seto-shi (JP); Hiroshi Yoshida, Anjo-shi (JP)

(73) Assignee: TOYOTA JIDOSHA KABUSHIKI KAISHA, Toyota-shi (JP)

(21) Appl. No.: 18/894,352

(22) Filed: Sep. 24, 2024

(30) Foreign Application Priority Data
Dec. 20, 2023 (JP) 2023-214646

(51) Int. Cl. B60L 58/16; B60L 58/12

(52) U.S. Cl. CPC B60L 58/16; B60L 58/12; B60L 2240/545

(57) ABSTRACT

The battery ECU updates the frequency data of the area using the temperature TB and SOC of the battery as parameters, and estimates the degradation degree (degradation amount) from the frequency data and the degradation coefficient that increases as the temperature TB increases. The degradation degree is stored in the control ECU. When the battery ECU is replaced, the battery ECU acquires the degradation level from the control ECU and creates a new frequency based on the degradation level. The new frequency data is created as frequency data F of an area having a high temperature TB and a large SOC, and the other area is set to a NULL.

### CROSS-REFERENCE TO RELATED APPLICATION

This application claims priority to Japanese Patent Application No. 2023-214646 filed on Dec. 20, 2023, incorporated herein by reference in its entirety.

### BACKGROUND

### 1. Technical Field

The present disclosure relates to a battery system and an electrified vehicle.

### 2. Description of Related Art

Japanese Unexamined Patent Application Publication No. 2023-109010 (JP 2023-109010 A) discloses a technique of restoring an amount of degradation of a battery when a battery electronic control unit (ECU) for calculating a cumulative amount of damage to a battery mounted on a vehicle is replaced. JP 2023-109010 A describes that an amount of degradation of a battery can be appropriately restored without being affected by the communication time for information that is received from an electronic fuel injection (EFI) ECU.

### SUMMARY

As the battery temperature increases, the degradation of the battery progresses more. Therefore, there are cases where the degree of degradation (amount of damage and amount of degradation) of a battery is estimated according to Arrhenius law using the frequency distribution (history) of the battery temperature. In this case, as the frequency of the high temperature state increases, the degree of degradation of the battery increases (the degradation of the battery is accelerated more).

The frequency distribution of the battery temperature is a history of the battery temperature during the period of use of the battery. Hereinafter, this history data is also referred to as “frequency data.” As the battery is used for a longer period, the amount of frequency data increases.

When a control device (battery ECU in JP 2023-109010 A) that estimates the degree of degradation is replaced, no frequency data is present in a memory of the replaced control device. In order to estimate the degree of degradation in the replaced control device, the frequency data stored in a memory of another control device (EFIECU in JP 2023-109010 A) may be written (read) into the memory of the replaced control device. However, there is a concern that the memory area of the frequency data may overflow when the battery is used for a long period thereafter (after the replacement of the control device).

An object of the present disclosure is to estimate the degree of degradation of a battery using frequency data when a control device that estimates the degree of degradation is replaced, and to suppress an overflow of a memory area of the control device.

A battery system of the present disclosure includes: a battery; a temperature sensor configured to detect a battery temperature that is a temperature of the battery; a first control device configured to estimate a degree of degradation of the battery; and a second control device configured to communicate with the first control device. The first control device is configured to estimate the degree of degradation using frequency data of the battery temperature and a degradation coefficient set to increase a degradation rate as the battery temperature increases. The second control device is configured to store the degree of degradation estimated by the first control device in a memory. When the first control device is replaced, the replaced first control device is configured to acquire the degree of degradation from the second control device. The replaced first control device is configured to create new frequency data to cause the frequency data in a region in which the degradation rate is equal to or higher than a predetermined value to indicate the degree of degradation acquired from the second control device, and estimate the degree of degradation using the new frequency data and the degradation coefficient.

With this configuration, the first control device estimates the degree of degradation using the frequency data of the battery temperature and the degradation coefficient set to increase the degradation rate as the battery temperature increases. The memory of the second control device stores the degree of degradation estimated by the first control device.

When the first control device is replaced, no frequency data on the battery is present in the replaced first control device. Therefore, the degree of degradation of the battery cannot be estimated using the frequency data.

With this configuration, when the first control device is replaced, the replaced first control device acquires the degree of degradation from the second control device, and creates the new frequency data to cause the frequency data in the region in which the degradation rate is equal to or higher than the predetermined value to indicate the degree of degradation acquired from the second control device. The replaced first control device estimates the degree of degradation using the new frequency data and the degradation coefficient. Therefore, the replaced first control device can estimate the degree of degradation of the battery using the new frequency data and the degradation coefficient.

The new frequency data is created to cause the frequency data in the region in which the degradation rate is equal to or higher than the predetermined value to indicate the degree of degradation acquired from the second control device. Since the degradation rate is set to increase as the battery temperature increases, the region for which the new frequency data is created is, for example, a high temperature region that is a predetermined temperature or higher. Batteries are typically used less frequently at temperatures lower than and higher than a normal operating temperature range. Since the battery is less frequently used in the high temperature region for which the new frequency data is created, the memory area of the first control device is less likely to overflow after the replacement. The degradation coefficient is set to increase the degradation rate as the battery temperature increases. Therefore, the amount of data is smaller when the frequency data is created to indicate the degree of degradation acquired from the second control device in the high temperature region of the battery temperature (region in which the degradation rate is equal to or higher than the predetermined value) than when the frequency data is created to indicate the degree of degradation acquired from the second control device in a low temperature region of the battery temperature (region in which the degradation rate is low). Thus, the memory area of the replaced first control device is less likely to overflow.

Preferably, the frequency data may be a history of the battery temperature and a state of charge (SOC) of the battery.

The degradation rate of a battery varies with its SOC, and degradation tends to be accelerated in, for example, a high SOC region. With this configuration, since the frequency data is a history of the battery temperature and the SOC of the battery, and the degree of degradation is estimated in view of the SOC, the estimation accuracy of the degree of degradation can be improved.

Preferably, the second control device may be configured to store the degree of degradation in the memory when the battery system is shut down, and the first control device may be configured to store the frequency data in a nonvolatile memory of the first control device when the battery system is shut down.

With this configuration, the second control device stores the degree of degradation in the memory when the battery system is shut down. The first control device is replaced after the system is shut down. Therefore, the degree of degradation can be read securely from the second control device when the first control device is replaced. The frequency data is stored in the nonvolatile memory of the first control device when the system is shut down. Therefore, the frequency data is less likely to be erased even in the event of a power outage of the first control device.

Preferably, the degree of degradation may be a capacity decrease amount of the battery.

With this configuration, a current full charge capacity can be easily estimated using the capacity decrease amount and, for example, overcharge of the battery can be suppressed.

An electrified vehicle according to the present disclosure is an electrified vehicle including the above battery system.

With this configuration, even after the first control device is replaced, the degree of degradation of the battery mounted on the vehicle can be estimated.

According to the present disclosure, it is possible to estimate the degree of degradation of the battery using the frequency data when the control device that estimates the degree of degradation is replaced, and to suppress the overflow of the memory area of the control device.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is an entire configuration diagram of an electrified vehicle in which a battery system according to the present embodiment is mounted;

FIG. 2 is a flow chart illustrating an exemplary battery degradation estimation process performed in the battery ECU;

FIG. 3A is a diagram for explaining a degradation factor and a frequency according to the present embodiment;

FIG. 3B is a diagram for explaining a degradation factor and a frequency according to the present embodiment;

FIG. 3C is a diagram for explaining a degradation factor and a frequency according to the present embodiment;

FIG. 4 is a flow chart illustrating an exemplary process of replacing a battery ECU executed in a battery ECU after replacement; and

FIG. 5 is a diagram illustrating a relation between the temperature TB and the frequency (cumulative times).

### DETAILED DESCRIPTION OF EMBODIMENTS

Hereinafter, an embodiment of the present disclosure will be described in detail with reference to the drawings. In the drawings, the same or corresponding parts are denoted by the same reference numerals, and the description thereof will not be repeated.

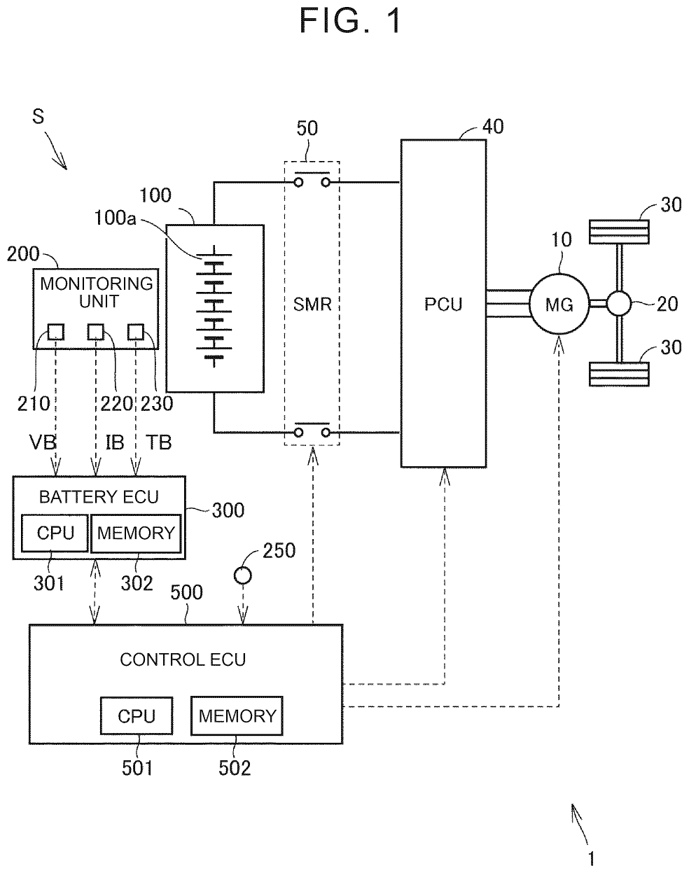

FIG. 1 is an entire configuration diagram of an electrified vehicle 1 in which a battery system S according to the present embodiment is mounted. In the present embodiment, electrified vehicle 1 is, for example, a battery electric vehicle. Electrified vehicle 1 may be a hybrid electric vehicle equipped with an internal combustion engine and a battery. Electrified vehicle 1 includes a motor generator (MG: Motor Generator) 10 which is a rotary electric machine, power transmission gears 20, drive wheels 30, a power control unit (PCU: Power Control Unit) 40, a system main relay (SMR: System Main Relay) 50, a battery 100, a monitoring unit 200, a battery ECU (Electronic Control Unit) 300 which is an example of a first control device, and a control ECU 500 which is an example of a second control device.

MG 10 is, for example, an embedded-structure permanent-magnet synchronous motor (IPM motor), and has a function as an electric motor and a function as a generator. The output-torque of MG 10 is transmitted to the drive wheels 30 via the power transmission gears 20 including a speed reducer, a differential, and the like.

When electrified vehicle 1 is braked, MG 10 is driven by the drive wheels 30, and MG 10 operates as a generator. As a result, MG 10 also functions as a braking device that performs regenerative braking for converting kinetic energy of electrified vehicle 1 into electric power. Regenerated electric power generated by regenerative braking force in the MG 10 is stored in the battery 100.

The PCU 40 is a power conversion device that bidirectionally converts electric power between the MG 10 and the battery 100. PCU 40 includes, for example, inverters and converters that operate based on control signals from the control ECU 500.

The SMR 50 is electrically connected to power lines connecting the battery 100 and the PCU 40. If SMR 50 is ON in response to a control signal from the control ECU 500, power may be exchanged between the battery 100 and PCU 40. On the other hand, when SMR 50 is OFF in response to a control signal from the control ECU 500, the battery 100 is disconnected from PCU 40.

The battery 100 stores electric power for driving MG 10. The battery 100 is a rechargeable DC power source (secondary battery), and is an assembled battery in which a plurality of unit cells (battery cells) 100a are electrically connected in series. The unit cell 100a may comprise, for example, a lithium-ion battery. The battery 100 corresponds to a “battery” of the present disclosure. Electrified vehicle 1 includes an inlet (not shown), and the battery 100 can be externally charged by connecting a plug (charging cable) of the charging facility to the inlet.

The monitoring unit 200 includes a voltage sensor 210, a current sensor 220, and a temperature sensor 230. The voltage sensor 210 detects a voltage VB of the battery 100. The current sensor 220 detects a current IB that is input to or output from the battery 100. The temperature sensor 230 detects a temperature TB of the battery 100. The temperature TB corresponds to the “battery temperature” disclosed herein. The sensor outputs the detected signal to the battery ECU 300.

The battery ECU 300 includes a CPU (Central Processing Unit) 301 and a memory 302. The memory 302 includes a RAM (e.g., SRAM (Static Random Access Memory)) and non-volatile memory (e.g., EEROM (Electrically Erasable Programmable Read-Only Memory)). When the power supply to RAM is stopped (when the power supply of the battery ECU 300 is lost), RAM loses stored data. In the non-volatile memory, even if the power supply of the battery ECU 300 is lost, the stored data does not disappear. The battery ECU 300 estimates SOC of the battery 100 using the signal received from the monitoring unit 200, and outputs the estimated signal to the control ECU 500. Further, the battery ECU 300 estimates the degree of degradation of the battery 100 and outputs it to the control ECU 500. The battery ECU 300 and the control ECU 500 may be connected by, for example, a CAN (Controller Area Network). In the present embodiment, the battery system S includes a battery 100, a monitoring unit 200, a battery ECU 300, a control ECU 500, and the like.

The control ECU 500 includes a CPU 501 and a memory 502. Memory 502, like memory 302, includes RAM and non-volatile memory. The control ECU 500 controls the devices so that electrified vehicle 1 is in a desired condition based on signals received from the battery ECU 300, signals from various sensors (not shown) (e.g., accelerator operation amount signal, vehicle speed signal, and the like), maps and programs stored in the memory 502, and the like.

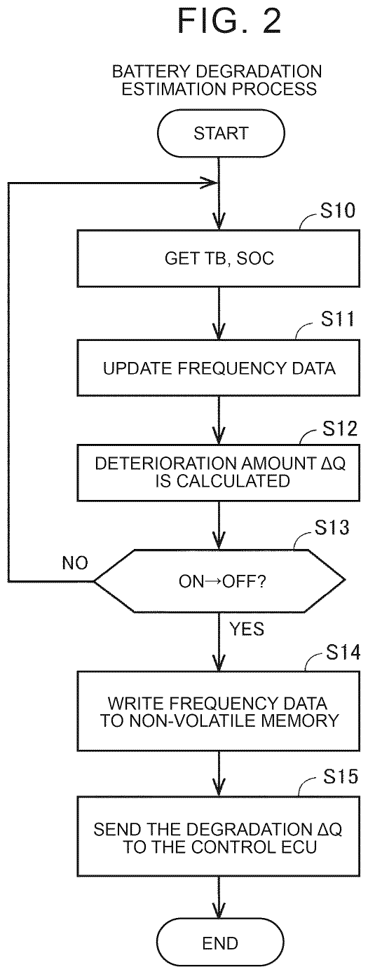

FIG. 2 is a flow chart illustrating an exemplary battery degradation estimation process performed in the battery ECU 300. This flow chart is executed when the power switch (ignition switch) 250 is turned ON and the battery system S is turned ON. When the power switch 250 is turned ON and the battery system S is turned ON, the temperature TB and SOC of the battery 100 are acquired in step (hereinafter, step is abbreviated as “S”) 10. The temperature TB may be detected by the temperature sensor 230. SOC may be calculated and acquired from SOC-OCV (Open Circuit Voltage of the battery 100) using the voltage VB detected by the voltage sensor 210.

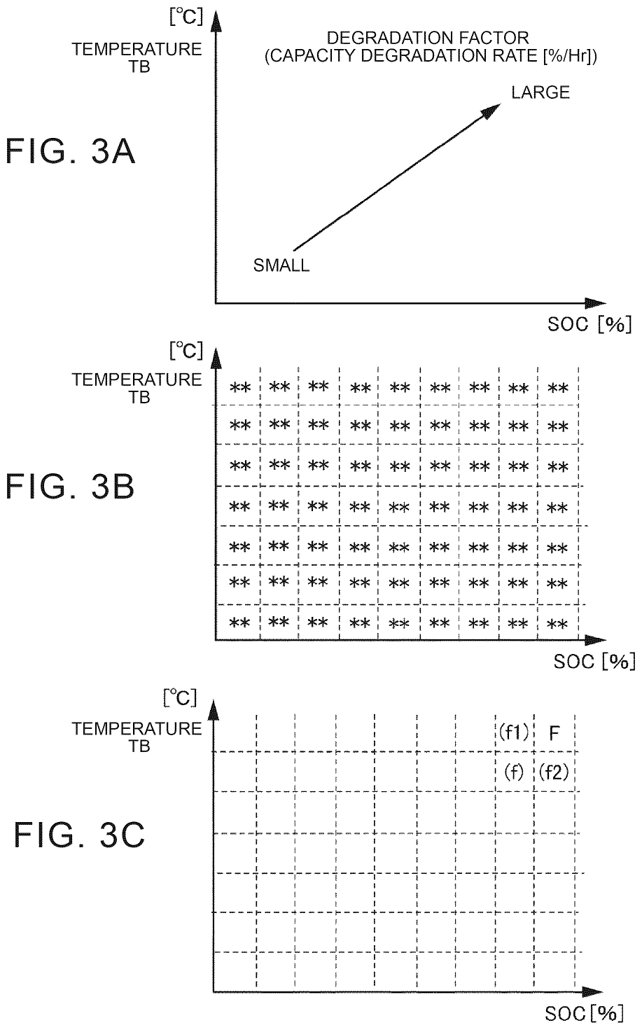

S11 updates the frequency based on the temperature TB and SOC acquired by S10. FIG. 3A, FIG. 3B, and FIG. 3C are diagrams for explaining degradation coefficients and frequency data in the present embodiment. FIG. 3A is a diagram for describing a degradation factor to be described later, and FIG. 3B is a diagram for describing frequency data updated in S11. In FIG. 3B shown in the drawing, the vertical axis represents the temperature TB [° C.] and the horizontal axis represents SOC [%]. In the present embodiment, the frequency data is the cumulative time of the time in which the battery 100 exists in the respective regions in the two-dimensional map using the temperature TB and SOC as parameters. For example, the temperature TB may range from −40° C. to +60° C., and SOC may range from 1% to 100%. Also, in the respective regions, the spacing between the temperature TB may be 1° C., or 2° C., or 5° C., and the spacing between SOC may be 1%, or 2%, or 5%. The cumulative time may be, for example, in units of one minute. In S11, the times of the regions corresponding to the temperature TB and SOC acquired by S10 are integrated (accumulated), and the frequency data is updated. The frequency data is stored in SRAM of the memory 302 and updated as needed by S11 being processed.

In the following S12, the degradation rate ΔQ of the battery 100 is calculated. The deterioration amount ΔQ is a deterioration amount (capacity deterioration amount) of the capacity [Ah] of the battery 100, and corresponds to an exemplary “deterioration degree” of the present disclosure. The degradation amount ΔQ is calculated based on the frequency data updated in S11 and the degradation coefficient. FIG. 3A are diagrams for explaining the degradation factors, where the vertical axis represents the temperature TB and the horizontal axis represents SOC. In the present embodiment, the degradation factor is the capacitance degradation rate [%/Hr]. Since the deterioration of the battery 100 is accelerated as the temperature TB is higher and SOC is higher (larger), the deterioration factor is set so that the higher the temperature TB and the higher SOC, the faster the capacity deterioration rate. In S12, the amount of capacity degradation of each region is obtained by multiplying the frequency data (cumulative time) and the degradation coefficient (capacity degradation rate) in each region, and the sum of the amount of capacity degradation is calculated as the degradation amount ΔQ. Note that the capacity degradation of the battery 100 (battery) is known to follow a route law (capacity degradation is proportional to the ½ power of time and cycle number), and the degradation capacity of each region may be obtained from the frequency data (cumulative time) and the degradation coefficient by using the route law.

In S13, it is determined whether or not the battery system S is turned OFF from ON. When the power switch 250 is operated from ON to OFF, it is determined that the battery system S is turned from ON to OFF, and the process proceeds to S14. When the power switch 250 is not operated, a negative determination is made and the process returns to S10, and S13 process is repeatedly executed from S10. S10 to S13 process may be performed at predetermined intervals.

In S14, the frequency data updated by S11 is written to the non-volatile memory of the memory 302, and then S15 proceeds. The frequency data stored in the nonvolatile memory of the memory 302 is used to restore the frequency data when the frequency data stored in SRAM of the memory 302 is lost or the like. For example, when a power line is disconnected from an output terminal of an auxiliary battery that is a power source of a battery ECU 300 during maintenance of an electrified vehicle 1 or the like, the frequency data may be lost.

In S15, the degradation amount ΔQ calculated by S12 is written into the nonvolatile memory of the memory 502 of the control ECU 500, and then the present routine is ended.

Battery ECU 300 may be replaced. Frequency data does not exist in the memory 302 (SRAM and the non-volatile memory) of the replaced battery ECU 300 (new battery ECU 300) (the area where the frequency data of SRAM and the non-volatile memory is stored is NULL). The degradation coefficient is stored in advance in the memory 302 according to the specifications of the battery 100. Therefore, in the battery ECU 300 after replacement, the degradation rate (degradation rate ΔQ) cannot be estimated using the frequency data.

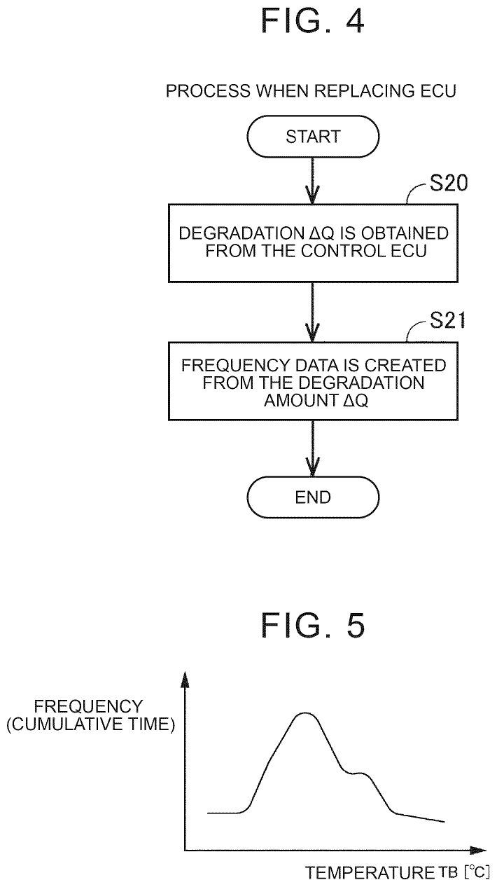

In the present embodiment, when the battery ECU 300 is replaced, the degradation amount ΔQ can be calculated by creating new frequency data using the degradation degree ΔQ stored in the control ECU 500. FIG. 4 is a flow chart illustrating an exemplary process of replacing a battery ECU performed in a battery ECU 300 after replacement. This flow chart is executed when the battery ECU 300 is replaced. For example, the cumulative travel distance of electrified vehicle 1 stored in the nonvolatile memory of the memory 302 of the battery ECU 300 is compared with the cumulative travel distance stored in the nonvolatile memory of the control ECU 500. Then, when the cumulative traveling distances are different, the flow chart may be executed so that it is determined that the battery ECU 300 has been replaced. The detecting of the replacement of the battery ECU 300 may be in any form.

When the battery ECU 300 is replaced, the new battery ECU 300 acquires, in S20, the degradation quantity ΔQ stored in the non-volatile memory of the memory 502 of the control ECU 500. For example, according to the requirement of the battery ECU 300, the degradation quantity ΔQ may be transmitted to the battery ECU 300 from the control ECU 500.

In the following S21, the frequency data is generated based on the obtained degradation amount ΔQ, and the routine is ended. In the present embodiment, the frequency data is created such that the frequency data in the area having the largest degradation coefficient (capacity degradation rate) becomes the degradation amount ΔQ obtained from the control ECU 500. For example, the frequency data F of the region having the highest temperature TB and the largest SOC (the region having the largest degradation coefficient) is calculated as F=ΔQ/S, where S is the degradation coefficient of the region. Then, as shown in FIG. 3C, frequency data of the region is set to F, and frequency data of the other region is maintained at NULL, and new frequency data is created. The new frequency data is stored in SRAM of the memory 302. (At this time, the new frequency data may be stored also in the non-volatile memory of the memory 302.) Thereafter, the new frequency data is updated in S11 of the battery degradation estimation process (FIG. 2).

According to the present embodiment, the battery ECU 300 estimates the degradation amount ΔQ by using the temperature TB, the frequency data of SOC, and the degradation coefficient set such that the higher the temperature TB, the higher the degradation rate (capacitance degradation rate). The control ECU 500 stores the degradation amount ΔQ estimated by the battery ECU 300 in the memory 502. When the battery ECU 300 is replaced, the battery ECU 300 after the replacement acquires the degradation quantity ΔQ from the control ECU 500. In the battery ECU 300 after the replacement, new frequency data is created such that the frequency data of the region having the highest temperature TB and the largest SOC (the region having the largest degradation coefficient) becomes the degradation amount ΔQ obtained from the control ECU 500. Then, the battery ECU 300 after the replacement estimates the degradation amount ΔQ using the new frequency data and the degradation coefficient.

FIG. 5 is a diagram illustrating a relation between the temperature TB and the frequency (cumulative times). In FIG. 5, the vertical axis represents frequency (cumulative time), and the horizontal axis represents temperature TB. As shown in FIG. 5, the battery 100 is generally used at a lower temperature side than the normal use temperature region and at a lower frequency than the normal use temperature region.

In the present embodiment, the new frequency data is created such that the frequency data in the region where the temperature TB is high and the degradation coefficient is the largest (the region where the capacitance degradation rate is the largest) becomes the degradation amount ΔQ. When the degradation coefficient of the region is S, the frequency data F of the region becomes F=ΔQ/S, and the frequency data of the other region remains null (NULL). As the degradation coefficient is larger, the frequency data F becomes a smaller value, and therefore, the amount of data is smaller than that of creating the frequency data from the degradation amount ΔQ in a region having a smaller degradation coefficient (a region having a slower capacity degradation speed). After that (after replacing the battery ECU 300), the temperature TB becomes high, and the frequency of presence in the area having the largest degradation factor is also small. Therefore, it is possible to prevent the frequency data from overflowing after the replacement of the battery ECU 300.

In the above-described embodiment, in S21 (FIG. 4), the frequency data F of the region having the highest temperature TB and the largest SOC (the region having the largest degradation coefficient) is calculated based on the degradation amount ΔQ, and new frequency data is created. However, the frequency data generated based on the degradation amount ΔQ may not be a region in which the temperature TB is the highest and SOC is the largest (a region in which the degradation coefficient is the largest). For example, in a region where the temperature TB is the second region from the highest temperature and SOC is the second largest, the frequency data f is calculated based on the degradation amount ΔQ. Then, as shown in FIG. 3C, the frequency data of the region may be set to f, and the frequency data of the other region may be maintained to be null.

In addition, the frequency data f1, f2 is calculated so that a value obtained by adding the degradation amount calculated from the frequency data f1 of the region having the highest temperature TB and the second largest SOC and the degradation amount calculated from the frequency data f2 of the region having the second highest temperature TB and the largest SOC is the degradation amount ΔQ. Then, as shown in FIG. 3C, the frequency data of the region may be set to f1, f2, and the frequency data of the other region may be maintained to be null. In the present disclosure, the “region where the degradation rate is equal to or higher than a predetermined value” may be, for example, any region of the upper 10% region where the capacity degradation rate is high (the degradation coefficient is large).

In the above-described embodiment, the frequency data is the cumulative time of the time in which the battery 100 exists in the respective regions in the two-dimensional map using the temperature TB and SOC as parameters. However, the frequency data may be cumulative times parameterized solely by the temperature TB. In addition, the frequency data may not be the cumulative time as long as it is a history corresponding to the time in which the battery 100 exists in the area.

In the above-described embodiment, in S12 (FIG. 2), the capacity degradation amount of each region is obtained from the frequency data (cumulative time) and the degradation coefficient (capacity degradation rate) in each region by using the route rule, and the sum of the capacity degradation amounts is calculated as the degradation amount ΔQ. When the deterioration amount Δq caused by the charging and discharging current is also calculated using the history data of the charging and discharging current of the battery 100, the added value (ΔQ+Δq) obtained by adding the deterioration amount Δq to the deterioration amount ΔQ may be stored in the control ECU 500 in S15. Here, in S21 (FIG. 4), the frequency data F may be calculated based on the added value (ΔQ+Δq), and new frequency data may be created.

When the route rule is used in determining the deterioration degree (deterioration amount ΔQ) of the battery 100, the capacity deterioration speed becomes slower as the use time of the battery 100 elapses. According to the present embodiment, the degradation amount ΔQ is acquired from the control ECU 500, and new frequency data is created from the degradation degree ΔQ. Therefore, since the new frequency data is created as data in which the use time of the battery 100 (the use time from the new time to the present time) is taken into account, it is possible to accurately estimate the degradation degree (degradation amount ΔQ) even after the replacement of the battery ECU 300.

The embodiment disclosed herein shall be construed as exemplary and not restrictive in all respects. The scope of the present disclosure is defined not by the above description of the embodiments but by the claims, and is intended to include all possible modifications within a scope equivalent in meaning and scope to the claims.

What is claimed is:

1. A battery system comprising: a battery; a temperature sensor configured to detect a battery temperature that is a temperature of the battery; a first control device configured to estimate a degree of degradation of the battery; and a second control device configured to communicate with the first control device, wherein:
the first control device is configured to estimate the degree of degradation using frequency data of the battery temperature and a degradation coefficient set to increase a degradation rate as the battery temperature increases;
the second control device is configured to store the degree of degradation estimated by the first control device in a memory; and
when the first control device is replaced, the replaced first control device is configured to
acquire the degree of degradation from the second control device,
create new frequency data to cause the frequency data in a region in which the degradation rate is equal to or higher than a predetermined value to indicate the degree of degradation acquired from the second control device, and
estimate the degree of degradation using the new frequency data and the degradation coefficient.

2. The battery system according to claim 1, wherein the frequency data is a history of the battery temperature and a state of charge of the battery.

3. The battery system according to claim 1, wherein:
the second control device is configured to store the degree of degradation in the memory when the battery system is shut down; and
the first control device is configured to store the frequency data in a nonvolatile memory of the first control device when the battery system is shut down.

4. The battery system according to claim 1, wherein the degree of degradation is a capacity decrease amount of the battery.

5. An electrified vehicle comprising the battery system according to claim 3.
